(19) United States
(12) Patent Application Publication
(10) Pub. No.: US 2013/0058016 A1
(43) Pub. Date: Mar. 7, 2013

(54) COVER ASSEMBLY AND PORTABLE ELECTRONIC DEVICE USING SAME

(71) Applicants: ZHENG SHI, Shenzhen City (CN); JIANG-FENG LIU, Shenzhen City (CN)

(72) Inventors: ZHENG SHI, Shenzhen City (CN); JIANG-FENG LIU, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/279,960

(22) Filed: Oct. 24, 2011

(30) Foreign Application Priority Data
Sep. 1, 2011 (CN) 201120325980.4

(51) Int. Cl. H05K 5/03; B32B 3/30; B32B 3/10

(52) U.S. Cl. 361/679.01; 428/201; 428/167; 428/203

(57) ABSTRACT

A cover assembly includes a cover, a grating and a pattern section. The grating is adhered to the cover. And the grating includes a first surface and a second surface opposite to the first surface. The first surface defines a granting surface. The pattern section is adhered on the second surface and located between the cover and the grating.

### CROSS-REFERENCE TO RELATED APPLICATIONS

The present application is related to one co-pending U.S. Patent Application (Attorney Docket No. U.S. Pat. No. 41,579), each entitled “COVER AND PORTABLE ELECTRONIC DEVICE USING SAME”, by Shi et al. These applications have the same assignee as the present application and have been concurrently filed herewith. The above-identified applications are incorporated herein by reference.

### BACKGROUND

1. Technical Field

The disclosure generally relates to a cover assembly and a portable electronic device using the same.

2. Description of the Related Art

Portable electronic devices (e.g. mobile phones) may include a cover and a two dimensional pattern (e. g. logo) printed on the cover, but the pattern is flat and uninteresting.

Therefore, there is room for improvement within the art.

### BRIEF DESCRIPTION OF THE DRAWINGS

Many aspects of the exemplary cover assembly and portable electronic device using same can be better understood with reference to the following drawings. The components in the various drawings are not necessarily drawn to scale, the emphasis instead being placed upon clearly illustrating the principles of the exemplary cover assembly and portable electronic device using same. Moreover, in the drawings, like reference numerals designate corresponding parts throughout the diagrams.

FIG. 1 is an exploded view of an exemplary portable electronic device.

FIG. 2 is an assembled view of the portable electronic device shown in FIG. 1.

FIG. 3 is a cross-sectional view of the portable electronic device shown in FIG. 1 along the line III-III.

### DETAILED DESCRIPTION

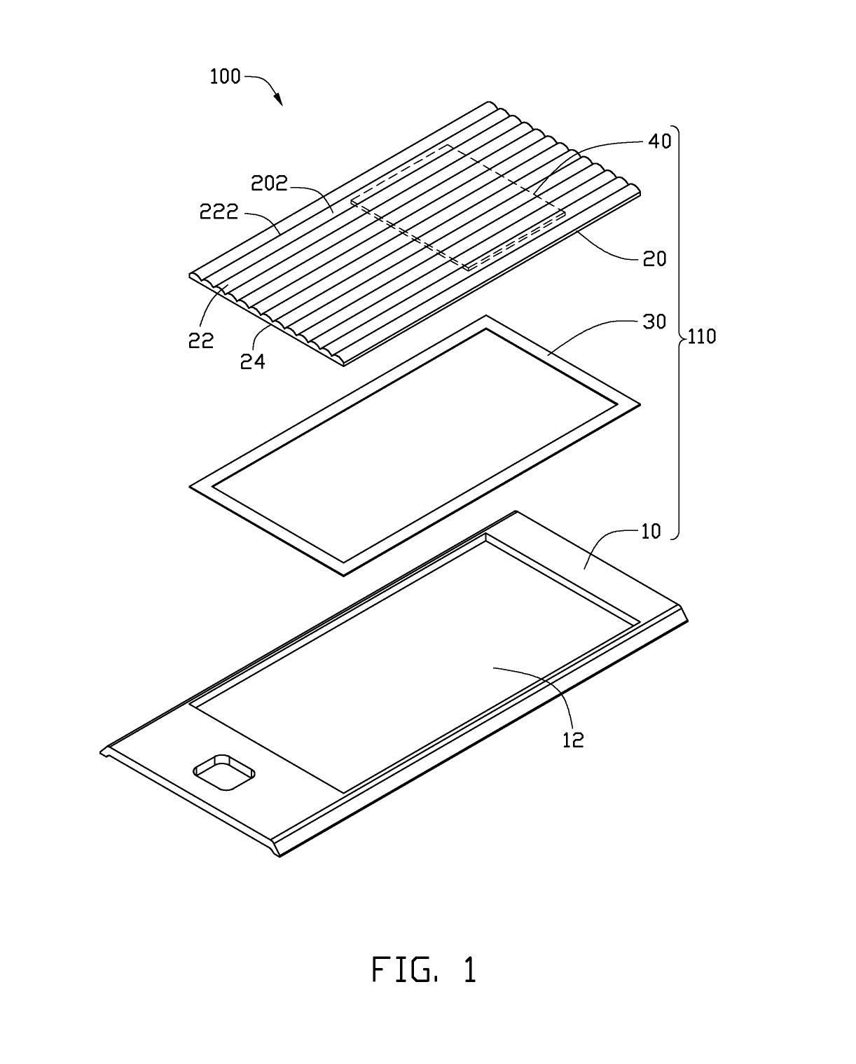

FIGS. 1 shows an exemplary portable electronic device 100 (e. g. mobile phone). The portable electronic device 100 includes a cover assembly 110. The cover assembly 110 includes a cover 10 and a grating 20 adhered to the cover 10 e.g., by double sided adhesive 30.

The cover 10 defines a mounting slot for mounting the grating 20. The grating 20 includes a first surface 22 and a second surface 24 opposite to the first surface 22. The first surface 22 defines a grating surface 202. The grating surface 202 is formed by defining a plurality of parallel grooves in the first surface 22. The cover assembly 110 further includes a pattern section 40 adhered on the second surface 22.

The grating 20 may be made of transparent or semi-opaque thermosetting material, such as one selected from a group of polycarbonate, polymethyl methacrylate, acrylonitrile butadiene styrene, and polystyrene.

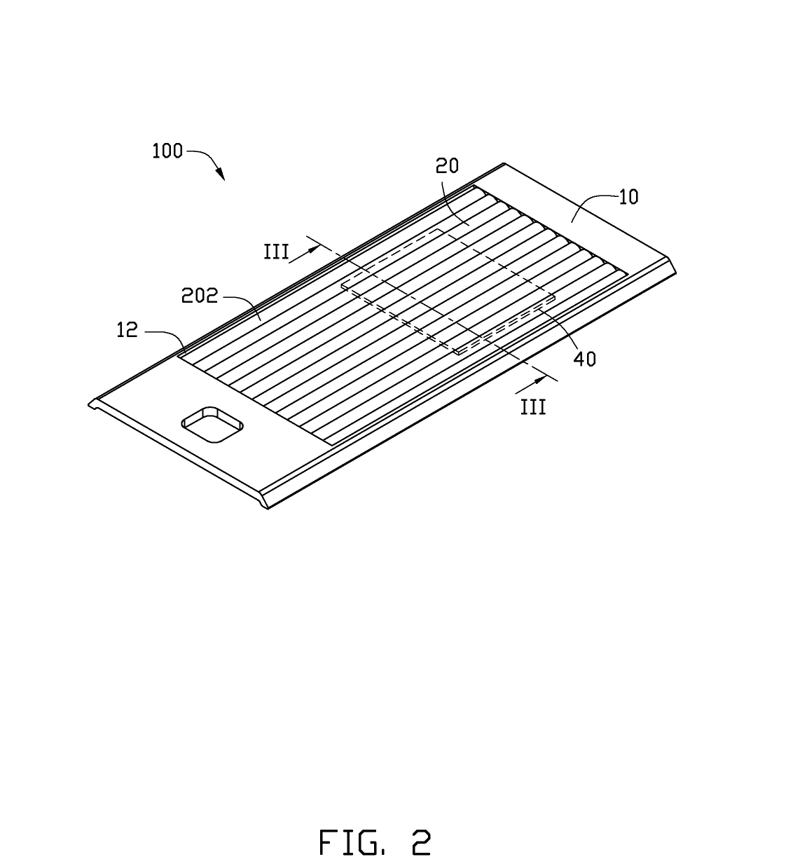

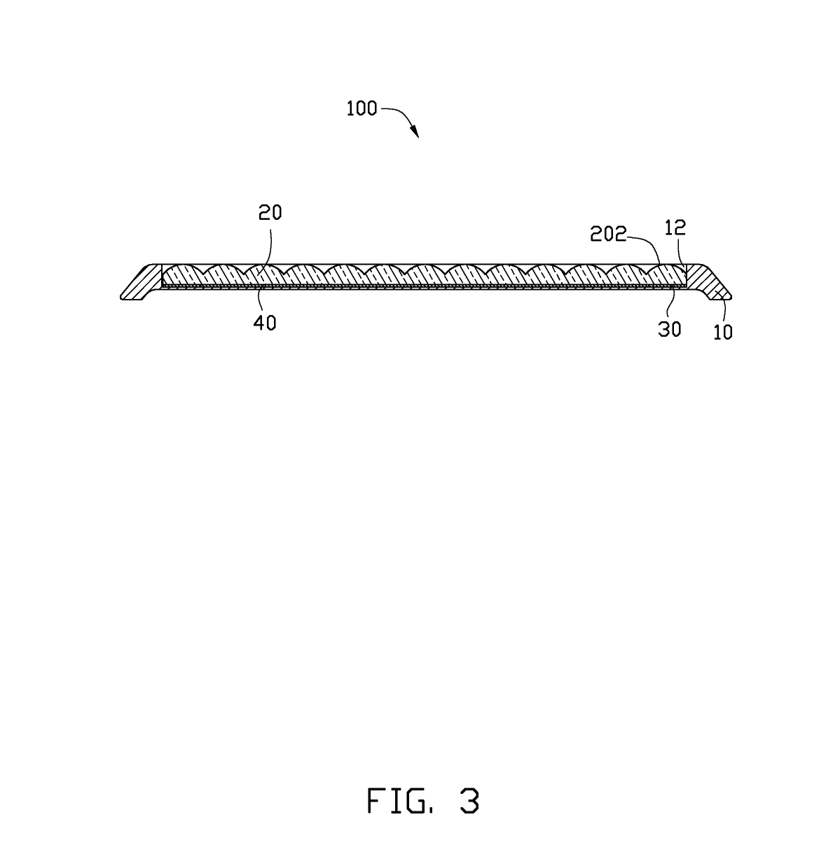

Referring to FIGS. 2 and 3, in assembly, the adhesive 30 adheres onto the second surface 24. The grating 20 and the adhesive 30 are retained in the mounting slot 12. The grating 20 presses the adhesive 30 onto the bottom of the mounting slot 12.

In use of the device 100, lighting through the plating surface 202 can give the pattern section 40 a three dimensional appearance.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A cover assembly comprises:
a cover; and
a grating adhered to the cover comprises:
a first surface defines a grating surface and a second surface opposite to the first surface;
a pattern section adhered on the second surface and sited between the cover and the grating.

2. The cover assembly as claimed in claim 1, wherein the cover defines a mounting slot for mounting the grating, and the second surface is adhered on the bottom of the mounting slot.

3. The cover assembly as claimed in claim 1, wherein the grating is adhered to the cover by double sided adhesive.

4. The cover assembly as claimed in claim 1, wherein the grating surface is formed by defining a plurality of parallel grooves in the first surface.

5. The cover assembly as claimed in claim 1, wherein the grating is made of transparent or semi-opaque material.

6. The cover assembly as claimed in claim 5, wherein the transparent or semi-opaque material is one selected from a group of polyethylene, polyvinyl alcohol, polypropylene, polycarbonate, polymethyl methacrylate, acrylonitrile butadiene styrene, and polystyrene.

7. The cover assembly as claimed in claim 6, wherein the transparent or semi-opaque material is polymethyl methacrylate.

8. A portable electronic device comprises:
a cover; and
a grating adhered to the cover comprises:
a first surface defines a grating surface and a second surface opposite to the first surface;
a pattern section adhered on the second surface and sited between the cover and the grating.

9. The portable electronic device as claimed in claim 8, wherein the cover defines a mounting slot for mounting the grating, and the second surface is adhered on the bottom of the mounting slot.

10. The portable electronic device as claimed in claim 8, wherein the grating is adhered to the cover by double sided adhesive.

11. The portable electronic device as claimed in claim 8, wherein the grating surface is formed by defining a plurality of parallel grooves in the first surface.

12. The portable electronic device as claimed in claim 8, wherein the grating is made of transparent or semi-opaque material.

13. The portable electronic device as claimed in claim 12, wherein the transparent or semi-opaque material is one selected from a group of polyethylene, polyvinyl alcohol, polypropylene, polycarbonate, polymethyl methacrylate, acrylonitrile butadiene styrene, and polystyrene.

14. The portable electronic device as claimed in claim 13, wherein the transparent or semi-opaque material is polymethyl methacrylate.
